(19) United States
(12) Patent Application Publication
(10) Pub. No.: US 2013/0058021 A1
(43) Pub. Date: Mar. 7, 2013

(54) CRADLE APPARATUS

(71) Applicant: Koichi Numata, Tokyo (JP)

(72) Inventor: Koichi Numata, Tokyo (JP)

(73) Assignee: Sony Corporation, Tokyo (JP)

(21) Appl. No.: 13/596,382

(22) Filed: Aug. 28, 2012

(30) Foreign Application Priority Data
Sep. 5, 2011 (JP) 2011-193031

(51) Int. Cl. H05K 7/18

(52) U.S. Cl. 361/679.01

(57) ABSTRACT

Disclosed herein is a cradle apparatus including: a cradle housing; a tray provided on the cradle housing and configured to receive an electronic apparatus placed thereon; a connector supporting portion provided for tilting motion on the tray; a connector supported on the connector supporting portion and configured to be electrically connected to the electronic apparatus; and a lever adapted to contact with a bottom face of the electronic apparatus connected to the connector and operate in response to the tilting motion of the connector supporting portion to push up the electronic apparatus.

### CROSS-REFERENCE TO RELATED APPLICATION

The present application claims priority from Japanese Patent Application No. JP 2011-193031 filed in the Japanese Patent Office on Sep. 5, 2011, the entire content of which is incorporated herein by reference.

### BACKGROUND

The present disclosure relates to a cradle apparatus, and particularly to a cradle apparatus configured to support an electronic apparatus.

An apparatus for supporting an electronic apparatus such as a portable music reproduction apparatus or a portable telephone set and electrically connecting to the electronic apparatus, that is, a cradle apparatus, has been heretofore utilized (refer to Japanese Patent Laid-Open No. 2008-253112). In such a cradle apparatus as just described, a connector configured to connect to an electronic apparatus is provided, and charging of the electronic apparatus and transmission and reception of data between the electronic apparatus and an external apparatus to which the cradle apparatus is connected can be achieved through the connector. Such a cradle apparatus as described above is used, for example, in a dock speaker.

### SUMMARY

In such a cradle apparatus as disclosed in Japanese Patent Laid-Open No. 2008-253112, in order to remove the electronic apparatus from the connector, a user pulls the electronic apparatus. If the electronic apparatus is pulled while it is tilted backward and forward in order to remove the electronic apparatus, then excessive force may be applied to the electronic apparatus and the connector and there is the possibility that the connector may be damaged.

Accordingly, it is desirable to provide a cradle apparatus which can prevent damage to a connector to which an electronic apparatus is to be connected.

According to an embodiment of the present disclosure, there is provided a cradle apparatus including: a cradle housing; a tray provided on the cradle housing and configured to receive an electronic apparatus placed thereon; a connector supporting portion provided for tilting motion on the tray; a connector supported on the connector supporting portion and configured to be electrically connected to the electronic apparatus; and a lever adapted to contact with a bottom face of the electronic apparatus connected to the connector and operate in response to the tilting motion of the connector supporting portion to push up the electronic apparatus.

According to the embodiment of the present disclosure, connection and disconnection of the connector and the electronic apparatus can be facilitated and damage to the connector can be prevented.

The above and other objects, features and advantages of the present disclosure will become apparent from the following description and the appended claims, taken in conjunction with the accompanying drawings in which like parts or elements denoted by like reference symbols.

### BRIEF DESCRIPTION OF THE DRAWINGS

FIG. 1 is a perspective view showing an appearance configuration of a dock speaker including a cradle apparatus;

FIG. 2 is a perspective view showing an appearance configuration of the cradle apparatus in a state in which an electronic apparatus is mounted thereon;

FIG. 3 is a perspective view showing an appearance configuration of the cradle apparatus;

FIG. 4A is a perspective view showing an appearance configuration of a cradle housing, and FIG. 4B is an exploded perspective view of the cradle housing;

FIG. 5 is a perspective view showing a back face side of an upper side case which configures the cradle housing;

FIG. 6 is a perspective view showing a configuration of a tray provided for sliding movement on the cradle housing;

FIGS. 7A to 7C are exploded perspective views of the tray showing the configuration of the tray;

FIG. 8 is a top plan view showing a configuration of a locking groove provided on the tray;

FIG. 9 is a perspective view showing a back face side of an upper side outer sliding portion which configures the tray;

FIG. 10A is a side elevational view and a top plan view showing a configuration of a lever provided on the tray,

FIG. 10B is a side elevational view and a top plan view showing a configuration of a connector supporting portion provided on the tray, and FIG. 10C is a side elevational view and a top plan view illustrating a positional relationship between the lever and the connector supporting portion;

FIG. 11A is a perspective view showing a bottom face side of an inner sliding portion which configures the tray, and FIG. 11B is a perspective view showing a lower face side of the cradle apparatus;

FIGS. 12A to 12C are side elevational views showing an operation of a movable stopper provided on the tray;

FIGS. 13A and 13B are side elevational views showing an operation of the lever provided on the tray;

FIGS. 14A to 14C are side elevational views showing operations of the lever and the connector supporting portion provided on the tray; and

FIG. 15A is a top plan view of the cradle apparatus, and FIG. 15B is a top plan view showing the configuration of the locking groove provided on the tray.

### DETAILED DESCRIPTION OF THE PREFERRED EMBODIMENT

In the following, an embodiment of the present disclosure is described with reference to the drawings. It is to be noted that the description is given in the following order.
<1. Embodiment>
   1-1. Configuration of Dock Speaker
   1-2. Configuration of Cradle Apparatus
   1-3. Operation of Cradle Apparatus
<2. Modification>

### <1. Embodiment>

1-1. Configuration of Dock Speaker

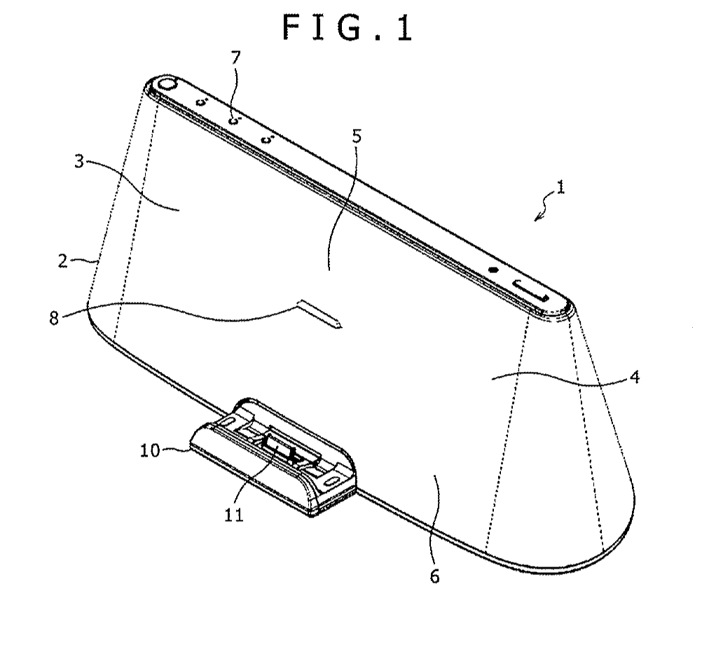

FIG. 1 is a perspective view showing an appearance configuration of a dock speaker 1 as a sound outputting apparatus. The dock speaker 1 includes a dock speaker housing 2, a Lch (left channel) speaker 3, a Rch (right channel) speaker 4, a woofer 5, a net 6, an operation section 7, a backrest section 8 and a cradle apparatus 10. Further, in the inside of the dock speaker 1, a control circuit, a reception antenna, a tuner, a storage medium, a sound processing circuit and an amplification section are provided although they are not shown.

The dock speaker housing 2 is formed such that opposite left and right ends thereof are rounded and a dimension thereof reduces toward an upper direction. However, the shape of the dock speaker housing 2 is not limited to this, but the dock speaker housing 2 may be formed in a different shape such as a rectangular shape. The dock speaker housing 2 is configured, for example, from synthetic resin such as a plastic material, aluminum or some other metal, and the speakers, the control circuit, the sound processing circuit and so forth are provided in the inside of the housing.

The Lch speaker 3 and Rch speaker 4 output sound data stored in an electronic apparatus 1000 connected to the dock speaker 1 as sound. In the dock speaker 1 shown in FIG. 1, the Lch speaker 3 and the Rch speaker 4 are provided in the dock speaker housing 2 in a state in which they are directed forwardly such that sound is outputted from a front face of the dock speaker housing 2.

In the present embodiment, the Lch speaker 3 is provided in the housing on the left side while the Rch speaker 4 is provided in the housing on the right side. Further, in the housing, the woofer 5 which is a low-frequency speaker is provided between the Lch speaker 3 and the Rch speaker 4. A front side of the dock speaker housing 2 is covered with a net member such as the net 6.

The operation section 7 has various operation buttons provided on an upper face of the dock speaker housing 2. For example, the operation section 7 includes a power button, a reproduction button, a stop button, a next-track button, a previous-track button and so forth. If an inputting operation is carried out to the operation section 7 by a user pushing the buttons, then a control signal representative of the inputting operation is generated and outputted to the control circuit. The control circuit carries out control of the dock speaker 1 in accordance with the control signal.

The backrest section 8, in the form of a projection, configured to support the electronic apparatus 1000 placed on the cradle apparatus 10 from behind projects at a substantially central portion in a widthwise direction in the front face of the dock speaker housing 2. The backrest section 8 is a projection having a predetermined length along the horizontal direction and the widthwise direction of the dock speaker housing 2. The electronic apparatus 1000 is supported from below by the cradle apparatus 10 and is supported from behind by the backrest section 8. It is to be noted that the backrest section 8 may not necessarily be provided, and the electronic apparatus 1000 may otherwise be supported only by the cradle apparatus 10.

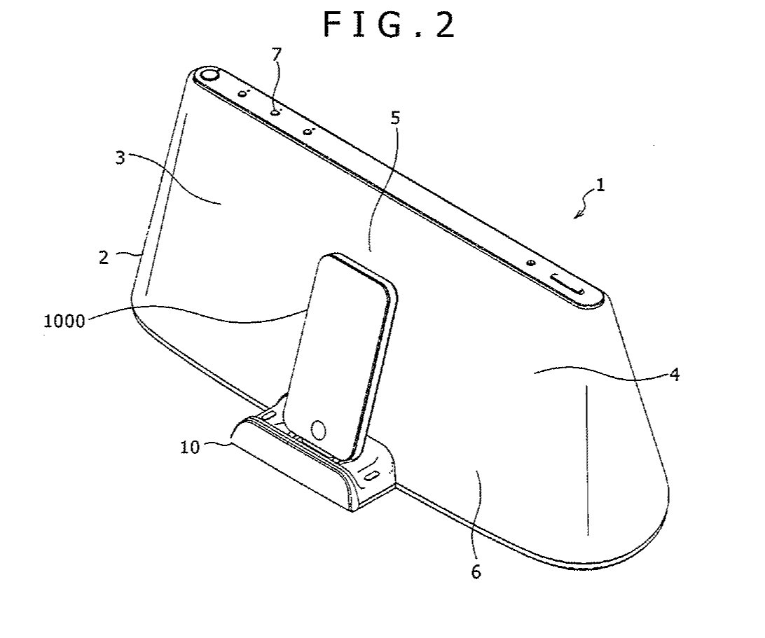

Referring to FIG. 2, the cradle apparatus 10 supports thereon the electronic apparatus 1000 connected to the dock speaker 1 such as a portable music reproduction apparatus, a portable telephone set, a smartphone, a portable game apparatus or a tablet terminal. Such members as just mentioned are hereinafter referred to collectively as electronic apparatus 1000. The cradle apparatus 10 includes a connector 11 and electrically connects the electronic apparatus 1000 to the dock speaker 1. Though not shown, the connector 11 is connected to the control circuit, the sound processing circuit and so forth in the inside of the dock speaker housing 2 by wiring lines.

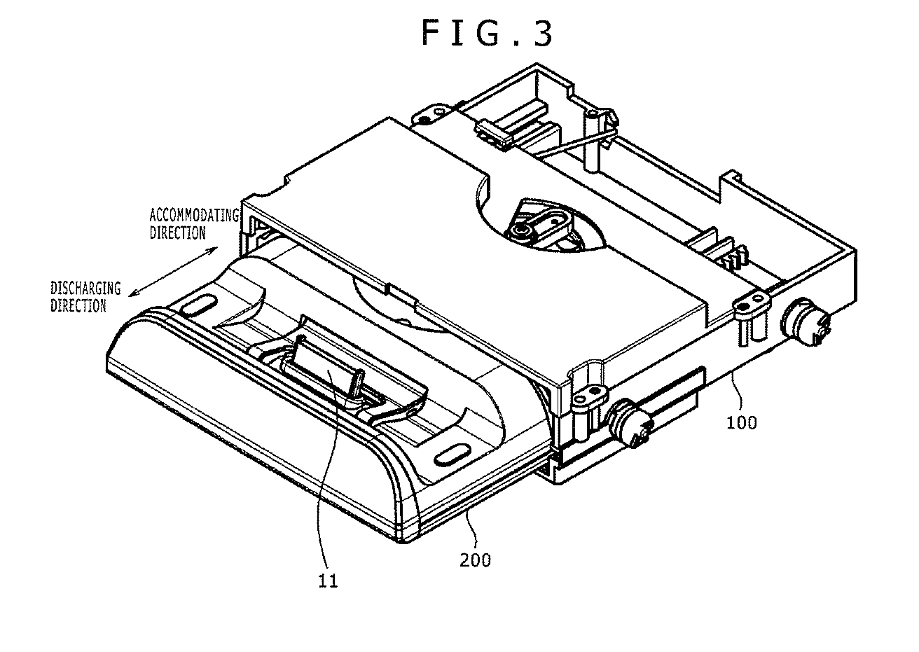

Referring to FIG. 3, the cradle apparatus 10 has a cradle housing 100 incorporated in the dock speaker housing 2 and a tray 200 configured for sliding movement in the cradle housing 100. The tray 200 can be accommodated at a sliding portion thereof in the dock speaker housing 2 when it is not used. When the tray 200 is to be used, the tray 200 is slid by the user to be discharged until the connector 11 is exposed to the outside. It is to be noted that a detailed configuration of the cradle apparatus 10 is described later.

The control circuit includes a CPU (Central Processing Unit), a RAM (Random Access Memory) and a ROM (Read Only Memory), for example. The CPU executes various processes in accordance with a program stored in the ROM using the RAM as a work memory to issue a command so that control of the entire dock speaker 1 is carried out.

The tuner is a terrestrial digital radio broadcasting tuner including a tuning circuit configured to tune a radio wave received by the reception antenna to a frequency corresponding to a selected channel, a demodulation circuit configured to carry out a demodulation process of a signal, and so forth. The tuner obtains a sound signal from a selected high-frequency signal and outputs the sound signal to the sound processing circuit and so forth. However, such a radio function as described above is not an essential configuration in the dock speaker 1.

The storage medium is a large-capacity storage medium having a nonvolatile memory or the like. Content data such as sound data is stored in the storage medium.

The sound processing circuit carries out predetermined processes such as a decoding process for music data transferred thereto from the electronic apparatus 1000 or the like and supplies resulting data to the amplification section. The amplification section carries out an amplification process for the sound signal supplied thereto and supplies a resulting signal to the speakers. Finally, sound obtained by the processes carried out by the sound processing circuit, the amplification section and so forth is outputted from the speakers.
1-2. Configuration of Cradle Apparatus

Now, a configuration of the cradle apparatus 10 is described. FIG. 3 is a perspective view showing an appearance configuration of the cradle apparatus 10. Referring to FIG. 3, the cradle apparatus 10 includes the cradle housing 100 and the tray 200 provided for sliding movement in the cradle housing 100. The connector 11 to which the electronic apparatus 1000 is to be connected is provided on the tray 200. The cradle housing 100 and the tray 200 are formed using a synthetic resin such as plastics.

The tray 200 is configured for sliding movement in an accommodating direction and a discharging direction in the cradle housing 100. In order to connect the electronic apparatus 1000 to the connector 11, the tray 200 is slid in the discharging direction to expose the connector 11 to the outside. When the electronic apparatus 1000 is not to be connected to the connector 11, the tray 200 is slid in the accommodating direction to accommodate the tray 200 into the cradle housing 100. It is to be noted that, in the following description, a state in which the tray 200 projects from the cradle housing 100 and the connector 11 is exposed is referred to as a discharged state of the tray 200, and another state in which the tray 200 is accommodated in the cradle housing 100 is referred to as an accommodated state.

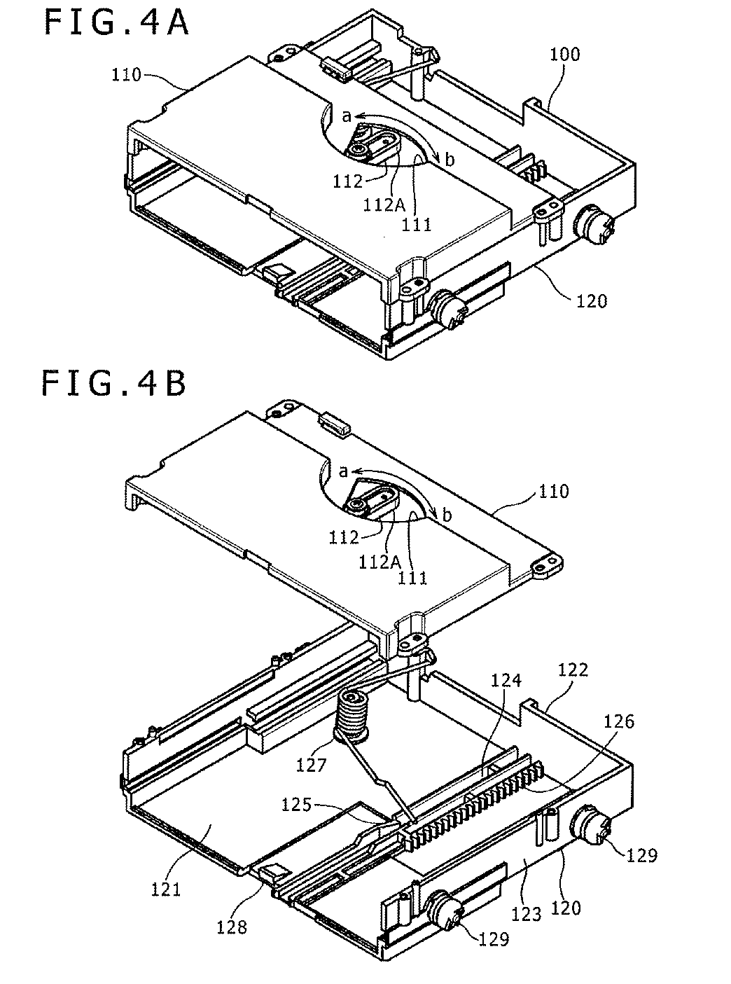

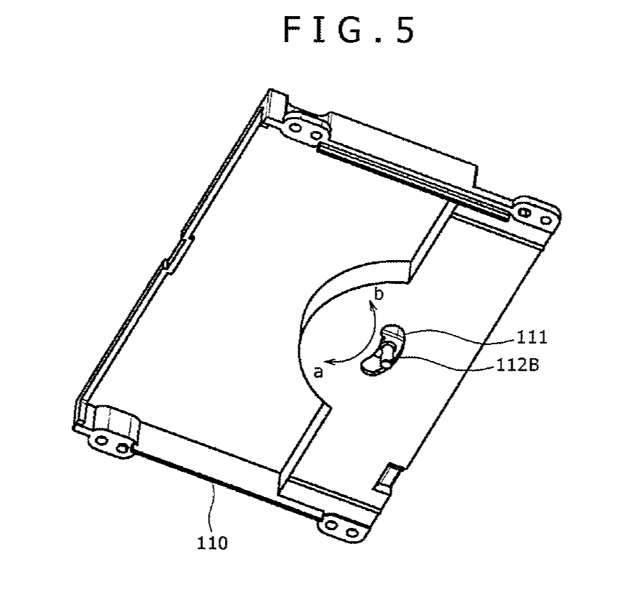

FIG. 4A is a perspective view showing an appearance configuration of the cradle housing 100. FIG. 4B is an exploded view showing a configuration of the cradle housing 100. Referring to FIG. 4A, the cradle housing 100 is a hollow tube which is open at the front thereof. Further, as seen in FIG. 4B, the cradle housing 100 has two members including an upper side case 110 and a lower side case 120. The upper side case 110 and the lower side case 120 are connected to each other, for example, by screws. FIG. 5 shows a back face side of the upper side case 110 which configures the cradle housing 100.

The upper side case 110 has a sectorial hole 111 formed in a substantially sectorial shape at a substantially middle portion in a widthwise direction thereof. A lock arm 112 is provided on the upper side case 110. The lock arm 112 is configured in a substantially L shape as viewed in side elevation and includes a pivotal arm 112A exposed to an upper face of the upper side case 110 as seen in FIGS. 4A and 4B and a locking projection 112B provided in such a manner as to project downwardly as seen in FIG. 5. The locking projection 112B provided on one end side of the pivotal arm 112A projects into the cradle housing 100 through the sectorial hole 111 formed on the upper face of the upper side case 110. The lock arm 112 is provided for movement in directions indicated by arrow marks a and b around the other end side thereof, which is secured by a screw or the like, on the upper side case 110.

Referring to FIG. 4B, the lower side case 120 has a rectangular bottom face portion 121, a back face portion 122 erected uprightly from a rear end edge of the bottom face portion 121, and side face portions 123 erected uprightly from opposite left and right end edges of the bottom face portion 121.

A linear guide groove 124 is provided on the bottom face portion 121 of the lower side case 120. A guide projection 550 is provided on the tray 200 hereinafter described and fitted for sliding movement in the guide groove 124. Since the tray 200 slides on the lower side case 120 in a state in which the guide projection 550 of the tray 200 is fitted in the guide groove 124, the tray 200 can slide linearly.

A slide stopping portion 125 in the form of a projection is provided at one end of the guide groove 124 and configured to collide with the guide projection 550 provided on the tray 200 to stop the sliding movement of the tray 200. If the tray 200 slides by a predetermined distance in the discharging direction, then the guide projection 550 is brought into collision with the slide stopping portion 125 to stop the sliding movement of the tray 200 in the discharging direction. Therefore, the tray 200 does not come out of the cradle housing 100.

A rack gear 126 in the form of a linear gear is provided on the bottom face portion 121. The rack gear 126 is engaged by a circular gear 560 hereinafter described provided on the tray 200. Upon the sliding movement of the tray 200, the circular gear 560 is rotated by the rack gear 126. This decelerates the sliding movement of the tray 200.

A helical torsion spring 127 is provided on the bottom face portion 121. The helical torsion spring 127 engages at one end thereof with the back face portion 122 of the cradle housing 100 and at the other end thereof with the guide projection 550 of the tray 200. The helical torsion spring 127 normally biases the tray 200 in the discharging direction by expanding spring force thereof. The tray 200 is thus slid in the discharging direction by the expanding force of the helical torsion spring 127. It is to be noted that the spring biasing the tray 200 in the discharging direction is not limited to the helical torsion spring 127 but may otherwise be, for example, a coil spring.

Further, the bottom face portion 121 has a tray engaging projection 128 configured to restrict the sliding movement of the tray 200, which is in the discharged state, in the accommodating direction to fix the tray 200 in the discharged stage. In the discharged state, a movable stopper 540 provided on the tray 200 engages with the tray engaging projection 128 to stop the sliding movement of the tray 200 in the accommodating direction, and consequently, the tray 200 is fixed in the discharged state.

A plurality of dampers 129 are provided on each of the side face portions 123. The cradle apparatus 10 is connected to the dock speaker 1 through the dampers 129. The entire cradle apparatus 10 is provided in a floating state on the dock speaker housing 2 through the dampers 129. Consequently, it is possible to suppress transmission of vibrations generated by the speakers provided in the dock speaker 1 to the cradle apparatus 10. Here, the floating state signifies a state in which the dock speaker housing 2 and the cradle apparatus 10 do not contact with each other and are not directly connected to each other but are connected indirectly through the dampers 129.

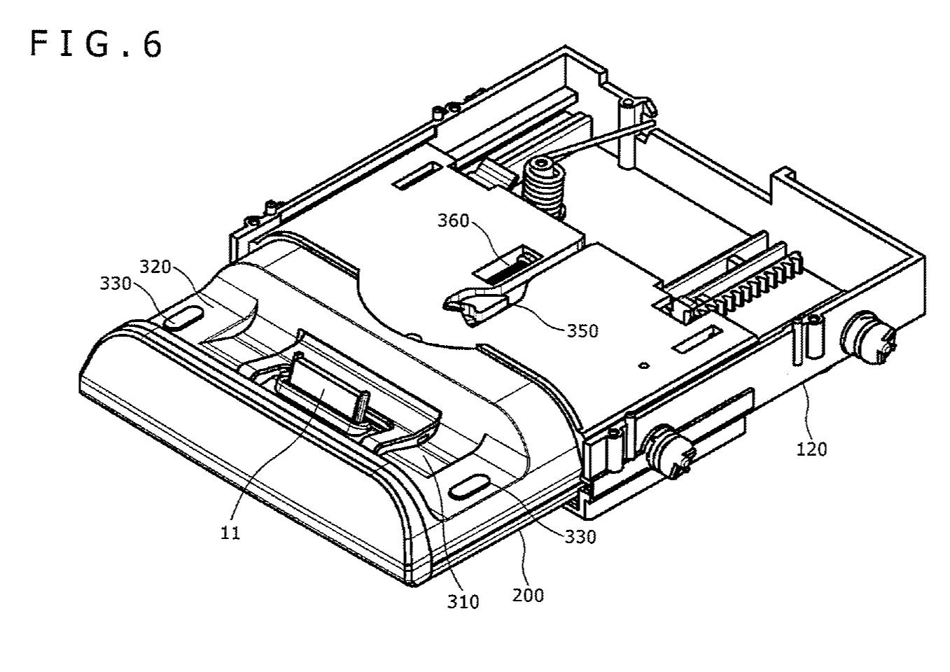

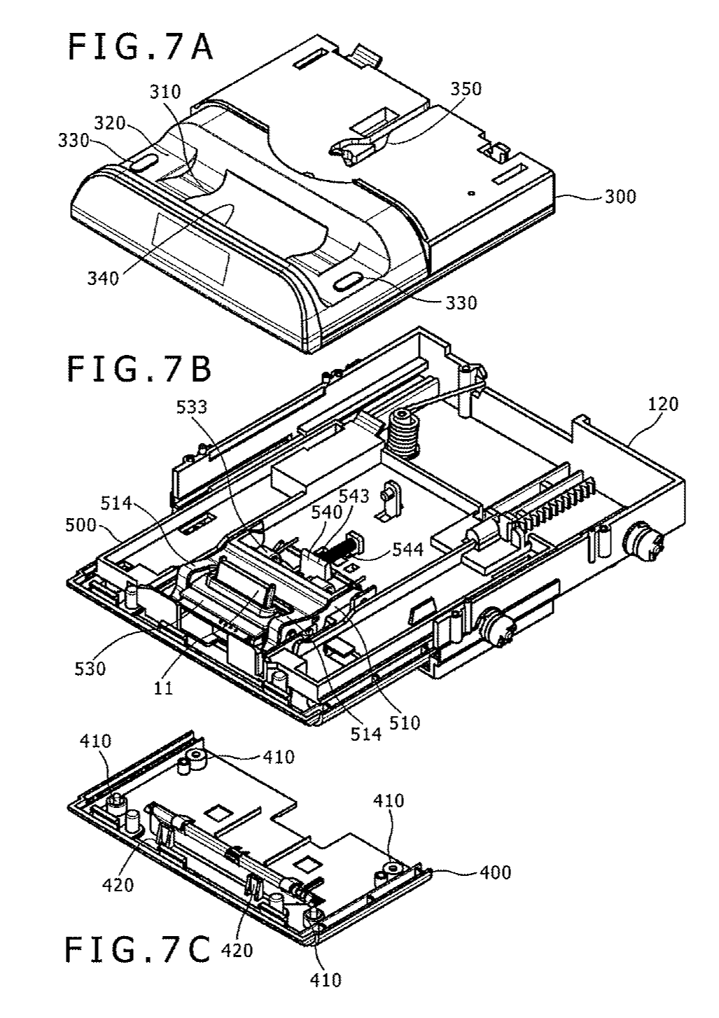

FIG. 6 is a view showing the tray 200 in a state in which it is provided for sliding movement in the cradle housing 100 with the upper side case 110 removed. FIGS. 7A to 7C are exploded perspective views showing a configuration of the tray 200 in the state in which it is provided for sliding movement on the cradle housing 100.

Referring to FIGS. 7A to 7C, the tray 200 includes three sliding portions: an upper side outer sliding portion 300; a lower side outer sliding portion 400; and an inner sliding portion 500. The upper side outer sliding portion 300 and the lower side outer sliding portion 400 are connected to each other with the inner sliding portion 500 sandwiched therebetween such that they can slide integrally with each other with respect to the inner sliding portion 500. The inner sliding portion 500 can slide on the cradle housing 100 relative to the lower side case 120. The upper side outer sliding portion 300 and the lower side outer sliding portion 400 connected for integral movement serve as an outer sliding portion in the claims.

The upper side outer sliding portion 300 has an inner side pedestal portion 310 and an outer side pedestal portion 320 provided at a front portion thereof. The inner side pedestal portion 310 is recessed deeply on the inner side while the outer side pedestal portion 320 is recessed more shallowly than the inner side pedestal portion 310 on the outer side of the inner side pedestal portion 310. The inner side pedestal portion 310 functions as a pedestal for an electronic apparatus of a comparatively small size such as a smartphone or a portable telephone set. The outer side pedestal portion 320 functions as a pedestal for an electronic apparatus of a comparatively large size such as a tablet terminal or a portable game machine. It is to be noted that the outer side pedestal portion 320 has a resilient member 330 of rubber or the like provided thereon to prevent the electronic apparatus 1000 placed thereon from being damaged.

An opening 340 is formed at a substantially middle portion in the inner side pedestal portion 310 and the outer side pedestal portion 320 of the upper side outer sliding portion 300 such that the connector 11 and a lever 510 provided on the inner sliding portion 500 are exposed through the opening 340.

Further, a locking groove 350 is provided at a substantially middle portion of a rear portion of the upper side outer sliding portion 300. The lock arm 112 is provided on the cradle housing 100, and the locking projection 112B thereof is inserted for sliding movement in the locking groove 350. The locking groove 350 cooperates with the lock arm 112 of the cradle housing 100 to configure a locking mechanism in a state in which the tray 200 is accommodated in the cradle housing 100.

Furthermore, an outer sliding portion returning spring 360 is provided on an upper face of the upper side outer sliding portion 300 which configures the tray 200 as seen in FIG. 6. The outer sliding portion returning spring 360 contacts on one end side thereof with the upper side outer sliding portion 300 and on the other end side thereof with the inner sliding portion 500, and normally biases the upper side outer sliding portion 300 in the discharging direction. The outer sliding portion returning spring 360 acts so that the upper side outer sliding portion 300 and the lower side outer sliding portion 400 slid in the accommodating direction with respect to the inner sliding portion 500 are returned in the discharging direction.

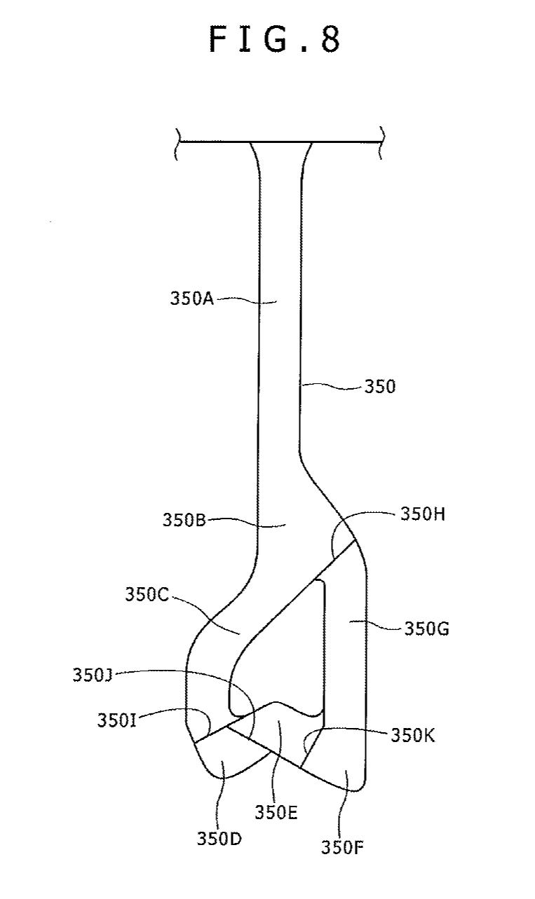

FIG. 8 is a partially enlarged plan view of the upper side outer sliding portion 300 showing a configuration of the locking groove 350. Referring to FIG. 8, the locking groove 350 has a linear portion 350A, a branching portion 350B, a first route portion 350C, a first folding back portion 350D, a locking portion 350E, a second folding back portion 350F and a second route portion 350G. Although details are hereinafter described, the locking portion 350E has a side face formed as a curved face, and if the locking projection 112B is positioned at the locking portion 350E, then it is caught by the side face of the locking portion 350E. Consequently, the tray 200 is locked against sliding movement in a state in which it is accommodated in the cradle housing 100. The locking projection 112B of the lock arm 112 moves from the linear portion 350A successively to the branching portion 350B, first route portion 350C, first folding back portion 350D and locking portion 350E in response to the sliding movement of the tray 200 in the accommodating direction. Further, the locking projection 112B moves from the locking portion 350E successively to the second folding back portion 350F, second route portion 350G and linear portion 350A in response to the sliding movement of the tray 200 in the discharging direction.

A first step 350H is formed on the boundary between the linear portion 350A and the second route portion 350G, and the second route portion 350G is positioned higher than the linear portion 350A. Further, a second step 3501 is formed on the boundary between the first route portion 350C and the first folding back portion 350D, and the first route portion 350C is positioned higher than the first folding back portion 350D. Further, a third step 350J is formed on the boundary between the first folding back portion 350D and the locking portion 350E, and the first folding back portion 350D is positioned higher than the locking portion 350E. Furthermore, a fourth step 350K is formed between the locking portion 350E and the second folding back portion 350F, and the locking portion 350E is positioned higher than the second folding back portion 350F. In this manner, the locking groove 350 is formed in a staircase shape having the plurality of steps. The reason why the steps are provided in this manner is that it is intended to prevent the locking projection 112B of the lock arm 112 from moving in a direction opposite to the moving direction described hereinabove. Details of locking of the tray 200 by the locking groove 350 and the lock arm 112 are hereinafter described.

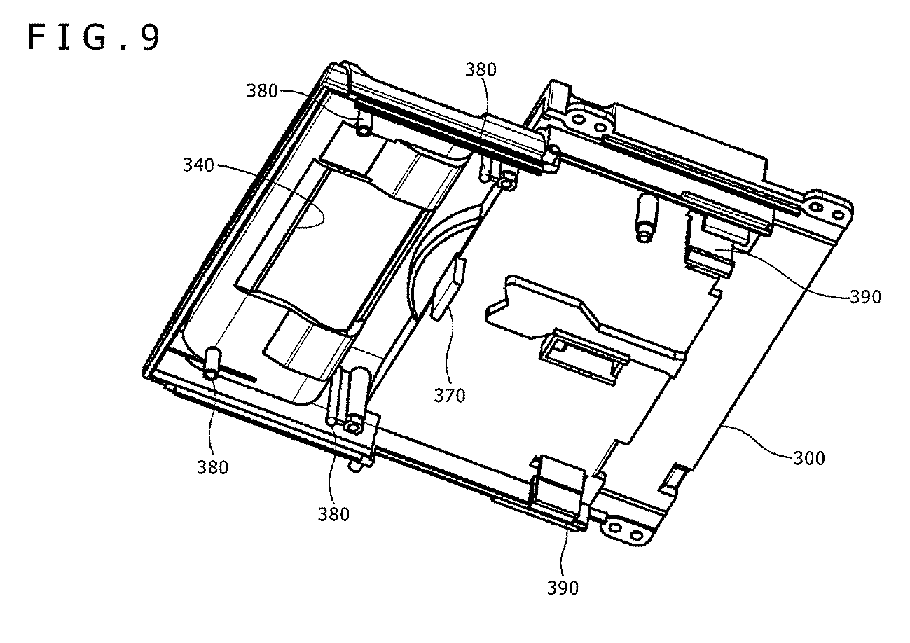

FIG. 9 shows a rear face side of the upper side outer sliding portion 300. Referring to FIG. 9, a pushing projection 370 is provided on the rear face of the upper side outer sliding portion 300. The pushing projection 370 pushes a movable projection 543 of the movable stopper 540 provided on the inner sliding portion 500 to move when the upper side outer sliding portion 300 slides in the accommodating direction with respect to the inner sliding portion 500. As a result, the movable stopper 540 moves to cancel the locking of the tray 200 in the discharged state thereby to permit the sliding movement of the tray 200 in the accommodating direction.

Further, four upper side fitting projections 380 configured to fit the upper side outer sliding portion 300 and the inner sliding portion 500 with each other and to connect the upper side outer sliding portion 300 and the lower side outer sliding portion 400 to each other are provided on the rear face side of the upper side outer sliding portion 300. Furthermore, two fitting pawls 390 configured to fit the upper side outer sliding portion 300 and the inner sliding portion 500 with each other are provided on the rear face side of the upper side outer sliding portion 300.

Referring back to FIG. 7C, a configuration of the lower side outer sliding portion 400 is described now. Four lower side fitting projections 410 configured to fit with the upper side fitting projections 380 of the upper side outer sliding portion 300 are provided on the lower side outer sliding portion 400. As the lower side fitting projections 410 and the upper side fitting projections 380 of the upper side outer sliding portion 300 are fitted with each other, the upper side outer sliding portion 300 and the lower side outer sliding portion 400 are connected to each other with the inner sliding portion 500 sandwiched therebetween. The upper side outer sliding portion 300 and the lower side outer sliding portion 400 connected to each other slide as a unitary member with respect to the inner sliding portion 500.

Further, on the lower side outer sliding portion 400, two lever contacting projections 420 are provided configured to be contacted by the lever 510 provided on the inner sliding portion 500. The lever contacting projections 420 are contacted by the lever 510 provided on the inner sliding portion 500 to restrict the sliding movement of the lower side outer sliding portion 400 and the upper side outer sliding portion 300 with respect to the inner sliding portion 500.

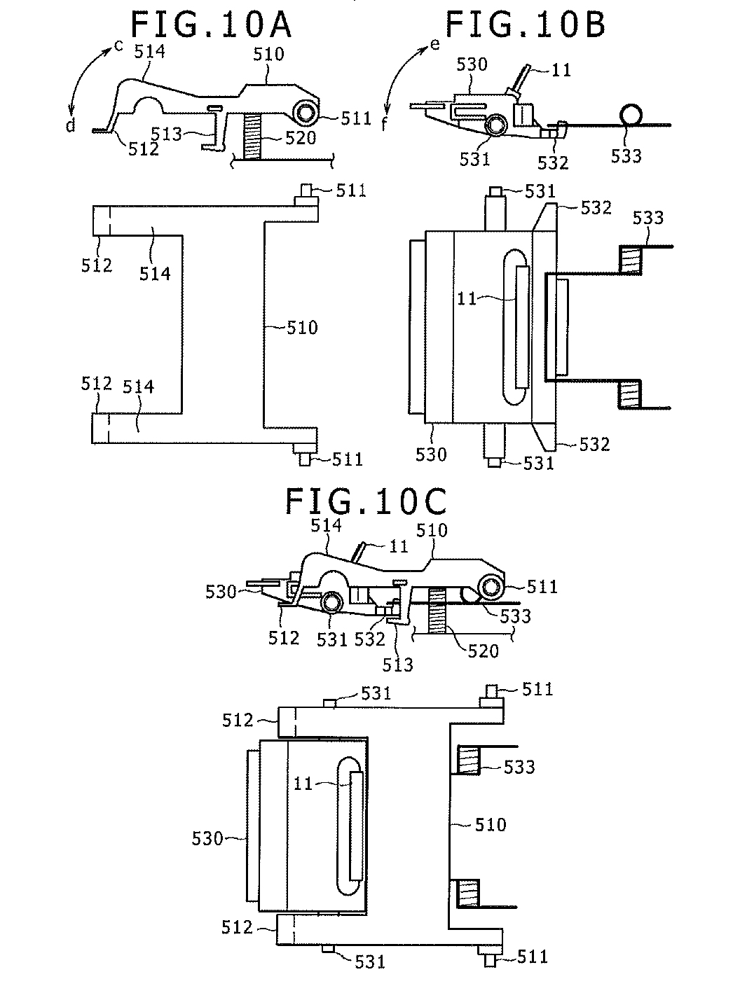

Now, a configuration of the inner sliding portion 500 is described with reference to FIGS. 7B and 10A to 10C. FIG. 10A is a side elevational view and a plan view showing a configuration of the lever 510 provided on the inner sliding portion 500. FIG. 10B is a side elevational view and a plan view showing a configuration of a connector supporting portion 530 provided on the inner sliding portion 500. FIG. 10C is a side elevational view and a plan view illustrating a positional relationship between the lever 510 and the connector supporting portion 530.

The inner sliding portion 500 is provided for sliding movement on the lower side case 120 which configures the cradle housing 100. The lever 510 is provided on the inner sliding portion 500. The lever 510 pushes up the electronic apparatus 1000 connected to the connector 11 from below and facilitates removal of the electronic apparatus 1000 from the connector 11. Further, since the lever 510 facilitates removal of the electronic apparatus 1000 from the connector 11 by pushing up the electronic apparatus 1000, also it is possible to prevent such a situation that the connector is damaged in error upon removal of the electronic apparatus 1000. Further, the lever 510 locks the upper side outer sliding portion 300 and the lower side outer sliding portion 400 against sliding movement in the accommodating direction. Furthermore, since the lever 510 operates by being pushed by the electronic apparatus 1000 connected to the connector 11, it is also possible to use the lever 510 to detect presence or absence of connection of the electronic apparatus 1000. Such roles of the lever 510 are hereinafter described.

The lever 510 is supported for pivotal motion on the inner sliding portion 500 by a lever pivot shaft 511 on one end side thereof such that it can be pivoted in directions indicated by arrow marks c and d around the lever pivot shaft 511. The lever 510 is normally biased by a lever pushing up spring 520 supported on a lower side portion thereof on the inner sliding portion 500 such that it is pivoted in the direction indicated by the arrow mark c.

The lever 510 has first arm portions 512, provided on the other end side thereof, of a substantially L shape which extend in a downward direction. Further, the lever 510 includes second arm portions 513 of a substantially L shape which extend in the downward direction. As seen in FIG. 10C, the second arm portions 513 are disposed at a position at which lever engaging projections 532 of the connector supporting portion 530 can engage therewith. An upper face portion of the lever 510 functions as an apparatus contacting portion 514 which is contacted with the electronic apparatus 1000 when the electronic apparatus 1000 connected to the connector 11 is pushed up.

As seen in the plan view of FIG. 10A, the lever 510 is formed in a bifurcated manner such that it has two first arm portions 512. The first arm portions 512 respectively contact at an end thereof with the two lever contacting projections 420 provided on the lower side outer sliding portion 400.

Further, the connector supporting portion 530 configured to support the connector 11 is provided on the inner sliding portion 500. As seen in FIG. 10B, the connector supporting portion 530 is supported for pivotal motion on the inner sliding portion 500 through a connector supporting portion pivot shaft 531. Consequently, the connector supporting portion 530 is configured for pivotal motion in directions indicated by arrow marks e and f around the connector supporting portion pivot shaft 531.

The lever engaging projections 532 are provided on the left and right of the connector supporting portion 530 such that they project outwardly. As seen in FIG. 10C, the lever engaging projections 532 are engaged with the second arm portions 513 of the lever 510. As the lever engaging projections 532 are engaged with the second arm portions 513 of the lever 510, the pivotal motion of the lever 510 in the direction indicated by the arrow mark c is restricted at a predetermined position. Further, when the connector supporting portion 530 is pivoted in the direction indicated by the arrow mark f, the lever engaging projections 532 are moved upwardly to push the lever 510 from below to pivot the lever 510 in the direction indicated by the arrow mark c.

The connector supporting portion 530 is normally biased by a double torsion spring 533 fixed to the inner sliding portion 500 such that an end thereof is pivoted in the direction indicated by the arrow mark e.

The connector 11 configured to electrically connect the electronic apparatus 1000 to the dock speaker 1 is provided at an upper portion of the connector supporting portion 530. In the figures, a 30-pin dock connector is shown as an example of the connector 11. However, the connector 11 is not limited to the 30-pin dock connector but may be any connector only if it is usable for the connection to an electronic apparatus such as a USB (Universal Serial Bus) connector, a Thunderbolt connector or a Firewire connector. The connector 11 is electrically connected to the control circuit and the like in the dock speaker 1 by a wiring line not shown.

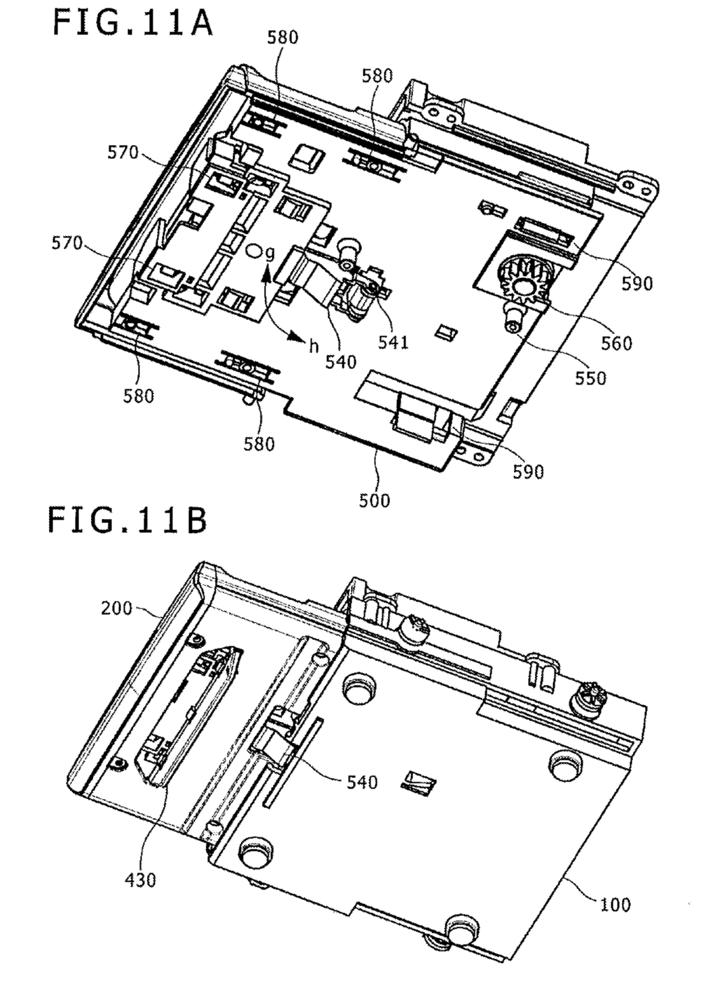

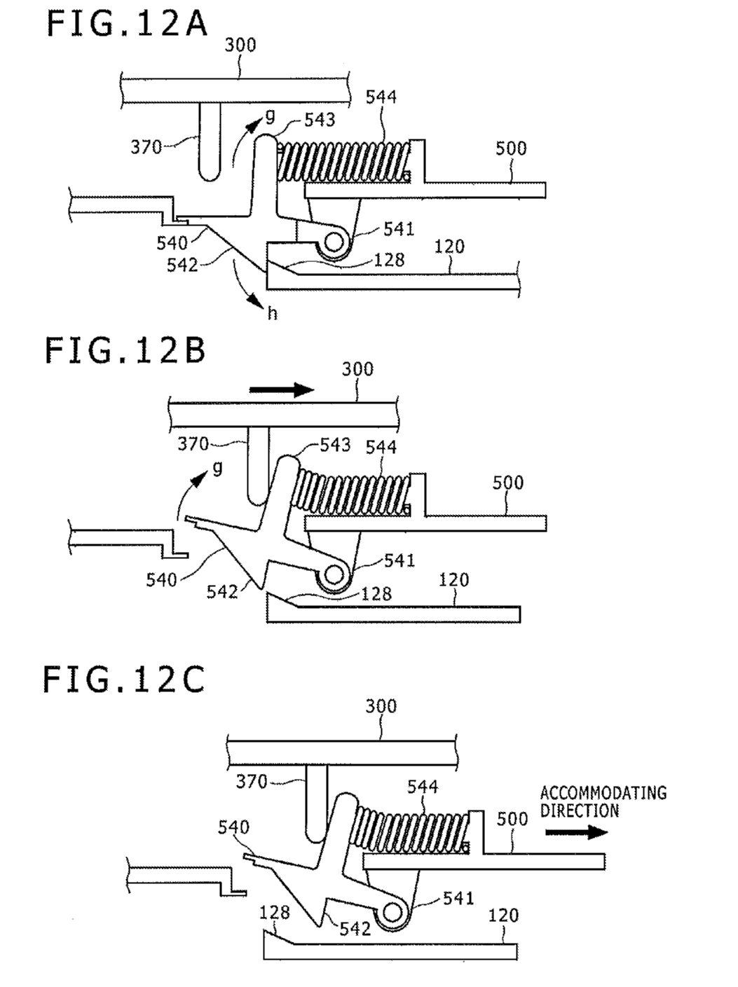

FIG. 11A is a view showing a configuration of a bottom face side of the inner sliding portion 500. FIG. 11B is a view showing a configuration of a bottom face side of the cradle housing 100 and the tray 200. Referring to FIGS. 7B, 11A and 11B, the movable stopper 540 is provided on the inner sliding portion 500. FIGS. 12A to 12C are side elevational views of the movable stopper 540. Referring also to FIGS. 12A to 12C, a stopper mechanism in the claims is configured from the movable stopper 540 and the tray engaging projection 128 provided on the lower side case 120 of the cradle housing 100.

The movable stopper 540 is supported for pivotal motion on the inner sliding portion 500 through a stopper pivot shaft 541 on a rear face of the inner sliding portion 500 as seen in FIGS. 11A and 12A to 12C. Consequently, the movable stopper 540 can pivot in directions indicated by arrow marks g and h around the stopper pivot shaft 541.

The movable stopper 540 has two projections including an engaging projection 542 extending downwardly and a movable projection 543 extending upwardly. As seen in FIGS. 11A and 11B, the engaging projection 542 is exposed to the outer side from the bottom face of the inner sliding portion 500. Meanwhile, the movable projection 543 is exposed from the upper face of the inner sliding portion 500 as seen in FIG. 7B.

The engaging projection 542 engages with the tray engaging projection 128 of the lower side case 120, which configures the cradle housing 100, in the discharged state of the tray 200. As the engaging projection 542 engages with the tray engaging projection 128, the sliding movement of the tray 200 in the accommodating direction is restricted to fix the tray 200 in the discharged state.

The movable stopper 540 is normally biased so as to be pivoted in the direction indicated by the arrow mark h by a stopper operating spring 544.

Further, as seen in FIG. 11A, the guide projection 550 is provided on a rear face side of the lower side outer sliding portion 400 such that it projects to the lower side. When the guide projection 550 advances into the guide groove 124 of the cradle housing 100, the tray 200 is permitted to slide straightforwardly with respect to the cradle housing 100.

Further, the circular gear 560 is provided for rotation on the rear face side of the inner sliding portion 500. The circular gear 560 engages with the rack gear 126 provided on the cradle housing 100. To a gear shaft not shown of the circular gear 560, a slight frictional load is applied using, for example, an O-ring not shown. When the tray 200 slides in the cradle housing 100, the circular gear 560 is rotated by the rack gear 126. Since the frictional load is applied to the circular gear 560, the speed of the sliding movement of the tray 200 is reduced to an appropriate speed by the frictional load.

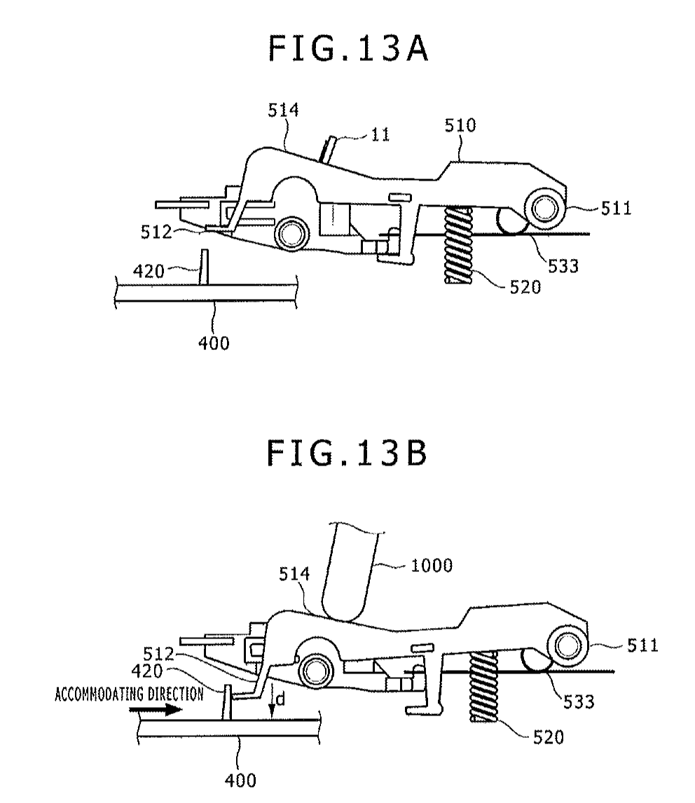

Further, two lever contacting projection insertion holes 570 are formed in the inner sliding portion 500. The lever contacting projections 420 of the lower side outer sliding portion 400 are inserted in the lever contacting projection insertion holes 570 in a state in which the upper side outer sliding portion 300 and the lower side outer sliding portion 400 are connected to each other with the inner sliding portion 500 sandwiched therebetween. As the lever contacting projections 420 of the lower side outer sliding portion 400 are inserted in the lever contacting projection insertion holes 570, the first arm portions 512 of the lever 510 and the lever contacting projections 420 can contact with each other as seen in FIG. 13B.

Furthermore, four fitting holes 580 are formed in the inner sliding portion 500. The four upper side fitting projections 380 provided on the upper side outer sliding portion 300 are respectively inserted in the four fitting holes 580. The four upper side fitting projections 380 are fitted with the four lower side fitting projections 410 provided on the lower side outer sliding portion 400 in the state in which they are inserted in the four fitting holes 580. Further, two pawl engaging portions 590 are provided on the inner sliding portion 500. The two fitting pawls 390 provided on the upper side outer sliding portion 300 are respectively fitted with the two pawl engaging portions 590. Consequently, the upper side outer sliding portion 300 and the lower side outer sliding portion 400 are connected to each other in the state in which the inner sliding portion 500 is sandwiched therebetween.

It is to be noted that, as seen in FIG. 11A, the four fitting holes 580 and the two pawl engaging portions 590 of the lower side outer sliding portion 400 are each formed in a substantially rectangular shape elongated in the sliding direction of the tray 200. Consequently, the upper side outer sliding portion 300 and the lower side outer sliding portion 400 can slide in the accommodating and discharging directions with respect to the inner sliding portion 500 by a length equal to the length of the fitting holes 580 and the pawl engaging portions 590. Although details are hereinafter described, the locking of the tray 200 in the discharged state is canceled by the sliding movement of the upper side outer sliding portion 300 with respect to the inner sliding portion 500.

As seen in FIG. 11B, a tray supporting plate 430 is provided on a lower face side of the lower side outer sliding portion 400. The tray supporting plate 430 functions as a foot which supports the tray 200 in the discharged state of the tray 200.
1-3. Operation of Cradle Apparatus

Now, operation of the cradle apparatus 10 configured in such a manner as described above is described. First, operation of the cradle apparatus 10 in a case where the sliding movement of the tray 200 in the accommodating direction is not restricted and the tray 200 slides in the accommodating direction from the discharged state thereof is described with reference to FIGS. 12A to 12C. FIGS. 12A to 12C are side elevational views showing the pushing projection 370 provided on the upper side outer sliding portion 300, the movable stopper 540 provided on the inner sliding portion 500, and the tray engaging projection 128 provided on the lower side case 120 of the cradle housing 100, extracted for the convenience of illustration.

FIG. 12A shows the tray 200 in the discharged state after it slides to an end of the sliding movement in the discharging direction. If the user pushes the tray 200 to slide the tray 200 in the accommodating direction from the discharged state, then since the upper side outer sliding portion 300 can slide with respect to the inner sliding portion 500, the upper side outer sliding portion 300 slides in the accommodating direction as seen in FIG. 12B. Consequently, the pushing projection 370 of the upper side outer sliding portion 300 is brought into contact with the movable projection 543 of the movable stopper 540 to push the movable projection 543 so that the movable stopper 540 is moved in the direction indicated by the arrow mark g. As a result, the engaging projection 542 of the movable stopper 540 is disengaged from the tray engaging projection 128 of the lower side case 120 as seen in FIG. 12C thereby to permit the sliding movement of the tray 200 in the accommodating direction.

Next, a case where the tray 200 is in the discharged state and the sliding movement of the tray 200 in the accommodating direction is restricted by the electronic apparatus 1000 connected to the connector 11 is described with reference to FIGS. 12A to 12C, 13A and 13B. The reason why the sliding movement of the tray 200 is restricted when the electronic apparatus 1000 is connected to the connector 11 is that, if the tray 200 is slid into the cradle housing 100, a load may be applied on the electronic apparatus 1000 and the connector 11, possibly causing damage on them.

FIGS. 13A and 13B are side elevational views showing the lever 510, lever pushing up spring 520, connector 11, connector supporting portion 530 and lever contacting projections 420 provided on the lower side outer sliding portion 400, extracted for the convenience of illustration.

FIG. 13A shows the elements mentioned above in a state in which the electronic apparatus 1000 is not connected to the connector 11. If the electronic apparatus 1000 is connected to the connector 11, then a bottom face of the electronic apparatus 1000 and the apparatus contacting portion 514 of the lever 510 are brought into contact with each other, whereupon the lever 510 is pushed in the direction indicated by the arrow mark d by the electronic apparatus 1000. Consequently, the lever 510 is pivoted in the direction indicated by the arrow mark d around the lever pivot shaft 511 as seen in FIG. 13B.

Consequently, the ends of the first arm portions 512 of the lever 510 move down to positions at which they contact with the lever contacting projections 420 of the lower side outer sliding portion 400 as seen in FIG. 13B. If, in this state, the tray 200 is pushed to move in the accommodating direction, then the lever contacting projections 420 of the lower side outer sliding portion 400 are brought into contact with the first arm portions 512 to restrict the sliding movement of the lower side outer sliding portion 400 in the accommodating direction with respect to the inner sliding portion 500.

As described hereinabove, the lower side outer sliding portion 400 and the upper side outer sliding portion 300 are connected to each other for integral movement. Therefore, when the sliding movement of the lower side outer sliding portion 400 with respect to the inner sliding portion 500 is restricted, also the sliding movement of the upper side outer sliding portion 300 with respect to the inner sliding portion 500 is restricted. Consequently, such a situation that the upper side outer sliding portion 300 slides and the pushing projection 370 pushes the movable projection 543 of the movable stopper 540 to move as seen in FIG. 12B does not occur. Therefore, the movable stopper 540 does not pivot in the direction indicated by the arrow mark g. Accordingly, the engaging projection 542 of the movable stopper 540 remains in engagement with the tray engaging projection 128, and the sliding movement of the tray 200 in the accommodating direction is restricted. Even if, in this state, the user pushes the tray 200 in the accommodating direction, since the engaging projection 542 of the movable stopper 540 is caught by the tray engaging projection 128, the tray 200 does not slide in the accommodating direction. Further, not only in the case in which the user pushes the tray 200 but also in a case in which some article collides with the tray 200, the tray 200 does not slide in the accommodating direction.

It is to be noted that, since, if the electronic apparatus 1000 is connected to the connector 11, then the lever 510 is pushed to pivot by the electronic apparatus 1000 as described hereinabove, presence or absence of the connection of the electronic apparatus 1000 can be detected mechanically from presence or absence of pivotal motion of the lever 510. Therefore, there is no necessity to provide such means as a circuit to electrically detect the connection of the electronic apparatus 1000 in order to detect the connection of the electronic apparatus 1000. Consequently, reduction of the number of parts, reduction of part cost and reduction of fabrication cost can be implemented. Further, also operation or changeover of a function of the dock speaker 1 associated with the presence or absence of the connection of the electronic apparatus 1000 can be implemented readily. As the operation of the dock speaker 1 associated with the presence or absence of the connection of the electronic apparatus 1000, for example, switching on/off of a power supply to the dock speaker 1 is applicable.

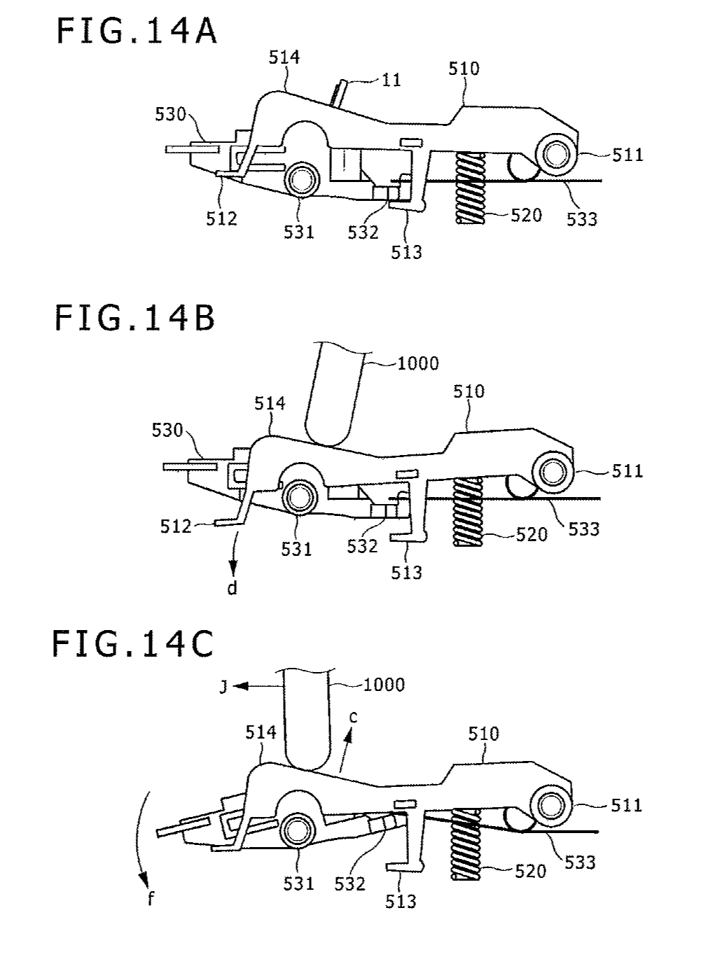

Now, operation upon connection and disconnection of the electronic apparatus 1000 to and from the connector 11 in a state in which the tray 200 is in the discharged state and the connector 11 is exposed outwardly is described with reference to FIGS. 14A to 14C.

FIGS. 14A to 14C illustrate operation of the lever 510 and the connector supporting portion 530 upon connection of the electronic apparatus 1000. It is to be noted that only the lever 510, lever pushing up spring 520, connector supporting portion 530 and double torsion spring 533 are shown, extracted for the convenience of description.

FIG. 14A shows the connector 11 in a state in which the electronic apparatus 1000 is not connected thereto. FIG. 14B shows the connector 11 in a state in which the electronic apparatus 1000 is connected thereto. If the electronic apparatus 1000 is connected to the connector 11, then the bottom face of the electronic apparatus 1000 and the apparatus contacting portion 514 of the lever 510 are brought into contact with each other, whereupon the lever 510 is pushed by the electronic apparatus 1000. Consequently, the lever 510 is pivoted in the direction indicated by the arrow mark d around the lever pivot shaft 511.

Then, if the user tilts the electronic apparatus 1000 in a direction indicated by an arrow mark J to try to remove the electronic apparatus 1000 from the connector 11, then the connector supporting portion 530 is pivoted in the direction indicated by the arrow mark f around the connector supporting portion pivot shaft 531 as seen in FIG. 14C. Thus, the lever engaging projection 532 of the connector supporting portion 530 moves upwardly to push up the lever 510. Consequently, the lever 510 pivots in the direction indicated by the arrow mark c. Further, since the lever 510 is normally biased in the direction indicated by the arrow mark c by the lever pushing up spring 520, the lever 510 is pivoted in the direction indicated by the arrow mark c by the lever pushing up spring 520. As a result, the lever 510 pushes up the electronic apparatus 1000 from below, and consequently, the electronic apparatus 1000 is removed readily from the connector 11.

In this manner, when the user tries to remove the electronic apparatus 1000 from the connector 11, if the user urges the electronic apparatus 1000 in the direction indicated by the arrow mark J, then the connector supporting portion 530 is pivoted, and also the electronic apparatus 1000 and the connector 11 are tilted in the direction indicated by the arrow mark J. Consequently, it can be prevented that a load is applied to the connector 11 and the connector 11 is damaged.

A function of detecting that the electronic apparatus 1000 is connected to the connector 11, another function of fixing the tray 200 in the discharged state and a further function of facilitating removal of the electronic apparatus 1000 by pushing up the electronic apparatus 1000 from below when the electronic apparatus 1000 connected to the connector 11 is to be removed can be implemented by operation of the lever 510. Consequently, the cradle apparatus 10 having the functions described above can be implemented by a comparatively small number of parts, and also reduction of the part cost and the fabrication cost can be implemented.

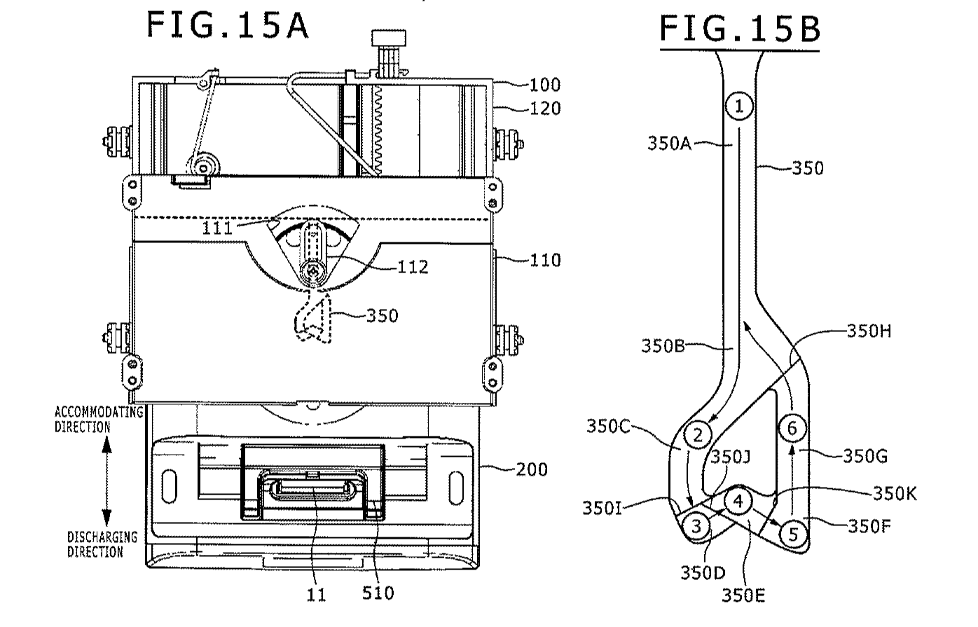

Now, locking and unlocking of the accommodated state of the tray 200 are described with reference to FIGS. 15A and 15B. FIG. 15A is a plan view of the cradle apparatus 10. For the convenience of illustration, the locking groove 350 provided on the upper side outer sliding portion 300 is indicated by a broken line. FIG. 15B is a plan view showing the configuration of the locking groove 350.

As described hereinabove, the locking projection 112B of the lock arm 112 provided on the upper side case 110 of the cradle housing 100 is inserted for sliding movement in the locking groove 350. When the tray 200 is in the discharged state, the locking projection 112B is positioned in the linear portion 350A as indicated by a position 1 illustrated in FIG. 15B. Further, if the tray 200 is slid in the accommodating direction, then the locking projection 112B advances from the linear portion 350A to the first route portion 350C through the branching portion 350B. It is to be noted that, since the first step 350H is provided on the boundary between the branching portion 350B and the second route portion 350G such that the second route portion 350G side is positioned higher than the branching portion 350B, the locking projection 112B does not advance into the second route portion 350G at all.

If the tray 200 is slid further in the accommodating direction, then the locking projection 112B advances from the first route portion 350C to the locking portion 350E through the first folding back portion 350D. Since the side face of the locking portion 350E is formed as a curved face such that the locking projection 112B is fitted therein, the locking projection 112B is caught by the locking portion 350E. Although the tray 200 is normally biased in the discharging direction by the helical torsion spring 127 so as to slide in the discharging direction, since the locking projection 112B is caught by the locking portion 350E of the locking groove 350, the sliding movement of the tray 200 in the discharging direction is restricted.

If, in a state in which the locking projection 112B is positioned at the locking portion 350E, that is, in a state in which the tray 200 is locked in the accommodated state, the user further pushes the tray 200 to move in the accommodating direction, then the tray 200 slides a little further in the accommodating direction from the accommodated state. Upon this sliding movement of the tray 200, the locking projection 112B advances from the locking portion 350E to the second folding back portion 350F. This is because, since the third step 350J is provided on the boundary between the first folding back portion 350D and the locking portion 350E such that the first folding back portion 350D is positioned higher than the locking portion 350E, when the locking projection 112B moves away from the locking portion 350E, the locking projection 112B does not advance to the first folding back portion 350D.

After the locking projection 112B is removed from the locking portion 350E, since the locking of the tray 200 in the discharging direction is canceled, the tray 200 begins to be slid in the discharging direction by the expanding force of the helical torsion spring 127. Then, the locking projection 112B advances through the second folding back portion 350F to the second route portion 350G, and upon the sliding movement of the tray 200 in the discharging direction, the locking projection 112B advances from the second route portion 350G to the linear portion 350A. It is to be noted that, since the fourth step 350K is provided on the boundary between the locking portion 350E and the second route portion 350G such that the locking portion 350E is positioned higher than the second route portion 350G, even if the locking projection 112B tries to advance from the second route portion 350G to the locking portion 350E, it is caught by the fourth step 350K. Consequently, the locking projection 112B does not advance from the second route portion 350G to the locking portion 350E at all.

In this manner, as the locking projection 112B of the lock arm 112 slides in the locking groove 350 until it is positioned at the locking portion 350E, the sliding movement of the tray 200 in the discharging direction is locked.

### <2. Modification>

Although the embodiment of the present disclosure has been described, the present technology is not limited to the embodiment described above and allows various modifications based on the technical scope thereof. For example, while, in the embodiment described above, the cradle apparatus 10 is provided in a dock speaker, the cradle apparatus can be applied to any apparatus such as an AV amplifier, a home theater system or a television receiver only if an electronic apparatus is connected thereto.

It is to be noted that the technology of the present disclosure can have such configurations as described below.
(1) A cradle apparatus, including:
   a cradle housing;
   a tray provided on the cradle housing and configured to receive an electronic apparatus placed thereon;
   a connector supporting portion provided for tilting motion on the tray;
   a connector supported on the connector supporting portion and configured to be electrically connected to the electronic apparatus; and
   a lever adapted to contact with a bottom face of the electronic apparatus connected to the connector and operate in response to the tilting motion of the connector supporting portion to push up the electronic apparatus.
(2) The cradle apparatus according to (1) described above,
   in which the connector supporting portion tilts in response to tilting of the electronic apparatus connected to the connector, and
   the lever operates in response to the tilting movement of the connector supporting portion to push up the electronic apparatus connected to the connector.
(3) The cradle apparatus according to (1) or (2) described above, further including a stopper mechanism adapted to fix the tray in a discharged state to the outside.
(4) The cradle apparatus according to (3) described above,
   in which the stopper mechanism includes
      a tray engaging projection provided on the cradle housing, and
      a stopper provided on the tray and adapted to engage with the tray engaging projection to fix the tray in the discharged state.
(5) The cradle apparatus according to (3) or (4) described above,
   in which the tray includes
      an inner sliding portion configured to slide with respect to the cradle housing, and
      an outer sliding portion configured to slide with respect to the inner sliding portion,
      the stopper is provided for upward and downward movement on the inner sliding portion,
      the outer sliding portion includes a pushing projection configured to push the stopper to move, and
      the outer sliding portion slides with respect to the inner sliding portion, then the pushing projection pushes the stopper so as to operate such that the stopper is disengaged from the tray engaging projection, and thus the discharged state of the tray is canceled.
(6) The cradle apparatus according to (4) or (5) described above,
   in which the lever includes an arm portion, and
   the electronic apparatus connected to the connector pushes the lever such that the arm portion is contacted with the outer sliding portion to restrict the sliding movement of the outer sliding portion thereby to prevent the pushing projection from pushing the stopper to lock the tray in the discharged state.
(7) The cradle apparatus according to any one of (1) to (6) described above, in which the lever is biased by an elastic member in a direction in which the electronic apparatus is pushed up.

It should be understood by those skilled in the art that various modifications, combinations, sub-combinations and alterations may occur depending on design requirements and other factors insofar as they are within the scope of the appended claims or the equivalents thereof.

What is claimed is:

1. A cradle apparatus, comprising:
a cradle housing;
a tray provided on the cradle housing and configured to receive an electronic apparatus placed thereon;
a connector supporting portion provided for tilting motion on the tray;
a connector supported on the connector supporting portion and configured to be electrically connected to the electronic apparatus; and
a lever adapted to contact with a bottom face of the electronic apparatus connected to the connector and operate in response to the tilting motion of the connector supporting portion to push up the electronic apparatus.

2. The cradle apparatus according to claim 1,
wherein the connector supporting portion tilts in response to tilting of the electronic apparatus connected to the connector, and
the lever operates in response to the tilting movement of the connector supporting portion to push up the electronic apparatus connected to the connector.

3. The cradle apparatus according to claim 1, further comprising a stopper mechanism adapted to fix the tray in a discharged state to the outside.

4. The cradle apparatus according to claim 3,
wherein the stopper mechanism includes
a tray engaging projection provided on the cradle housing, and
a stopper provided on the tray and adapted to engage with the tray engaging projection to fix the tray in the discharged state.

5. The cradle apparatus according to claim 4,
wherein the tray includes
an inner sliding portion configured to slide with respect to the cradle housing, and
an outer sliding portion configured to slide with respect to the inner sliding portion,
the stopper is provided for upward and downward movement on the inner sliding portion,
the outer sliding portion includes a pushing projection configured to push the stopper to move, and
the outer sliding portion slides with respect to the inner sliding portion, then the pushing projection pushes the stopper so as to operate such that the stopper is disengaged from the tray engaging projection, and thus the discharged state of the tray is canceled.

6. The cradle apparatus according to claim 5,
wherein the lever includes an arm portion, and
the electronic apparatus connected to the connector pushes the lever such that the arm portion is contacted with the outer sliding portion to restrict the sliding movement of the outer sliding portion thereby to prevent the pushing projection from pushing the stopper to lock the tray in the discharged state.

7. The cradle apparatus according to claim 1, wherein the lever is biased by an elastic member in a direction in which the electronic apparatus is pushed up.
